(19) United States
(12) Patent Application Publication
(10) Pub. No.: US 2015/0281610 A1
(43) Pub. Date: Oct. 1, 2015

(54) SOLID-STATE IMAGING APPARATUS AND IMAGING SYSTEM

(71) Applicant: CANON KABUSHIKI KAISHA, Tokyo (JP)

(72) Inventors: Yasuharu Ota, Kawasaki-shi (JP); Kazuki Ohshitanai, Kawasaki-shi (JP); Yu Arishima, Yokohama-shi (JP)

(21) Appl. No.: 14/666,478

(22) Filed: Mar. 24, 2015

(30) Foreign Application Priority Data
Apr. 1, 2014 (JP) 2014-075060

(51) Int. Cl. H04N 5/369; H01L 27/146

(52) U.S. Cl. CPC H04N 5/3698; H01L 27/14612; H01L 27/14627; H01L 27/14643

(57) ABSTRACT

Provided is a solid-state imaging apparatus, including: a plurality of photoelectric conversion elements each configured to generate charges by photoelectric conversion; and a plurality of transfer transistors, which are connected to the plurality of photoelectric conversion elements, respectively, each configured to transfer the generated charges to the same floating diffusion, in which the plurality of transfer transistors are each configured to be on/off controlled based on a voltage input to a gate terminal thereof, and a length of a period during which the voltage input to the gate terminal changes when a corresponding one of the plurality of transfer transistors is switched from on to off varies from one transfer transistor to another.

### BACKGROUND OF THE INVENTION

1. Field of the Invention

The present invention relates to a solid-state imaging apparatus and an imaging system.

2. Description of the Related Art

In Japanese Patent Application Laid-Open No. H09-46596, there is disclosed a solid-state imaging apparatus including pixels in which a plurality of photodiodes (PDs) are connected to the same floating diffusion (FD) via respective transfer transistors. There is also disclosed a configuration in which a control pulse for transferring charges is supplied to each of the transfer transistors connected to the same FD from a different signal line.

When the control pulse is input to the transfer transistor, if a pulse fall time (the period during which the logic level of the control pulse is switched from High to Low or from Low to High, that is, the period during which the transfer transistor is switched from on to off) is too short, some of the charges generated by the PD may return to the PD without being transferred to the FD. This phenomenon may lead to insufficient charge transfer efficiency, and image quality may degrade because a signal with lowered intensity is output from a pixel.

Meanwhile, parasitic capacitance exists between a signal line connected to the transfer transistor and the FD. Accordingly, the electric potential of the FD changes when a voltage is input to a gate terminal of the transfer transistor as a control signal. In the pixel configuration in which the plurality of PDs share the FD, the capacitance between the signal line connected to the transfer transistor and the FD may vary from one transfer transistor to another. In this case, the electric potential increase amount of the FD at the time of transfer of the charges of the PD varies from one PD to another, and hence the charge transfer efficiency may vary from one PD to another.

If image quality degradation caused by the above-mentioned factor is to be reduced by uniformly lengthening the fall times of the control pulses used to transfer the charges from the respective PDs, there may be a problem in that a longer time may be necessary for photography, and the number of images to be taken by the solid-state imaging apparatus per unit time may be reduced.

### SUMMARY OF THE INVENTION

According to one aspect of the present invention, there is provided a solid-state imaging apparatus, including: a plurality of photoelectric conversion elements each configured to generate charges by photoelectric conversion; and a plurality of transfer transistors, which are connected to the plurality of photoelectric conversion elements, respectively, each configured to transfer the generated charges to the same floating diffusion, in which the plurality of transfer transistors are configured to be on/off controlled based on a voltage input to a gate terminal thereof, and a length of a period during which the voltage input to the gate terminal changes when a corresponding one of the plurality of transfer transistors is switched from on to off varies from one transfer transistor to another.

Further features of the present invention will become apparent from the following description of exemplary embodiments with reference to the attached drawings.

### BRIEF DESCRIPTION OF THE DRAWINGS

FIG. 1 is a circuit configuration diagram of a solid-state imaging apparatus according to a first embodiment of the present invention.

FIG. 2 is a drive timing chart according to the first embodiment.

FIG. 3A is a schematic electric potential diagram illustrating residual electrons.

FIG. 3B is a schematic electric potential diagram illustrating residual electrons.

FIG. 4 is a circuit configuration diagram of a solid-state imaging apparatus according to a second embodiment of the present invention.

FIG. 5 is a drive timing chart illustrating the second embodiment.

FIG. 6 is a drive timing chart illustrating a third embodiment of the present invention.

FIG. 7 is a diagram illustrating a configuration of an imaging system according to a fourth embodiment of the present invention.

### DESCRIPTION OF THE EMBODIMENTS

Preferred embodiments of the present invention will now be described in detail in accordance with the accompanying drawings. Like components are denoted by like reference symbols throughout the drawings, and descriptions of overlapping components are sometimes omitted.

### First Embodiment

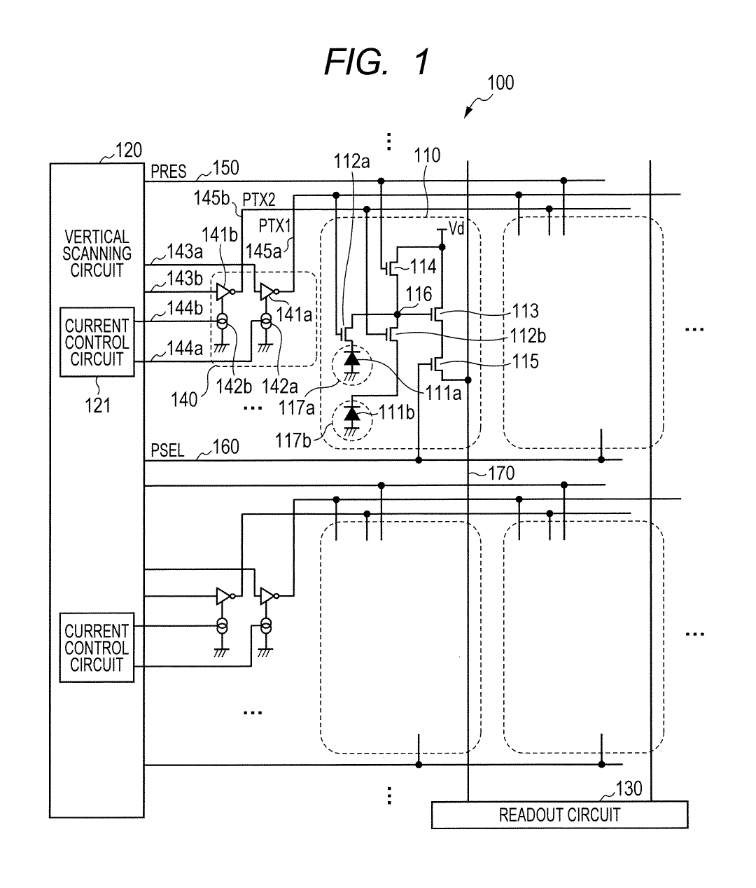

FIG. 1 illustrates a circuit configuration diagram of a solid-state imaging apparatus according to a first embodiment of the present invention. A solid-state imaging apparatus 100 includes a plurality of pixels 110 arranged in matrix, a vertical scanning circuit 120, a readout circuit 130, and a buffer unit 140. The vertical scanning circuit 120 includes a current control circuit 121.

The pixel 110 includes photodiodes (PDs) 111a and 111b, transfer transistors 112a and 112b, an amplifier transistor 113, a reset transistor 114, a select transistor 115, and a floating diffusion (FD) 116. Each transistor is formed of an N-type metal-oxide-semiconductor field-effect transistor (MOSFET) or the like, and functions as a switch or an amplifier. A first control signal PTX1 and a second control signal PTX2 are input to gate terminals of the transfer transistors 112a and 112b from the buffer unit 140 through transfer signal lines 145a and 145b, respectively. A control signal PRES is input to a gate terminal of the reset transistor 114 from the vertical scanning circuit 120 through a reset signal line 150. A control signal PSEL is input to a gate terminal of the select transistor 115 from the vertical scanning circuit 120 through a select signal line 160. Depending on the levels of voltages of the control signals, the respective transistors are controlled to be turned on (connected) or off (disconnected). The transfer signal lines 145a and 145b, the reset signal line 150, and the select signal line 160 are connected in common to the pixels 110 in each row. Herein, each transistor is turned on when the signal of High level is input to the gate terminal thereof, and turned off when the signal of Low level is input thereto.

Each of the PDs 111a and 111b is a photoelectric conversion element, which is configured to generate and accumulate, when irradiated with light, signal charges corresponding to the amount of light irradiation. The transfer transistor 112a is connected between the PD 111a and the FD 116, and the transfer transistor 112b is connected between the PD 111b and the FD 116. In other words, the PDs 111a and 111b share the same FD 116. When the control signals PTX1 and PTX2 become High level so that the transfer transistors 112a and 112b are turned on, the signal charges accumulated in the PDs 111a and 111b are transferred to the FD 116. The PDs 111a and 111b include microlenses 117a and 117b, respectively, as optical systems for converging incident light onto light receiving portions of the PDs.

The FD 116 is connected to drain terminals of the transfer transistors 112a and 112b, a gate terminal of the amplifier transistor 113, and a source terminal of the reset transistor 114. When the charges are transferred from the transfer transistors 112a and 112b to the FD 116, the electric potential of the FD 116 is changed. The amplifier transistor 113 outputs a signal corresponding to the electric potential of the FD 116 to the drain terminal of the select transistor 115.

The reset transistor 114 is a transistor for resetting the electric potential of the FD 116 to a reset electric potential Vd. When the reset transistor 114 is turned on based on the control signal PRES, the FD 116 is connected to interconnect having the reset electric potential Vd, and the charges transferred from the PDs 111a and 111b to the FD 116 are reset.

The select transistor 115 is a transistor for selecting a pixel row from which a signal is output. When the select transistor 115 is turned on based on the control signal PSEL, the signal output from the amplifier transistor 113 is output to the readout circuit 130 through a vertical output line 170.

The buffer unit 140 includes buffers 141a and 141b, and constant current sources 142a and 142b connected to the buffers 141a and 141b, respectively. The vertical scanning circuit 120 outputs the signals for controlling the transfer transistors to the buffers 141a and 141b through buffer input lines 143a and 143b. Each of the buffers 141a and 141b is a circuit for current-amplifying an input signal to output the amplified signal. The buffers 141a and 141b output the control signals PTX1 and PTX2 to the gate terminals of the transfer transistors 112a and 112b through the transfer signal lines 145a and 145b, respectively. In response to control signals from the current control circuit 121, the constant current sources 142a and 142b supply internal currents of the buffers 141a and 141b, respectively. Based on the internal currents, the amounts of currents that may be output from the buffers 141a and 141b are adjusted to determine fall times during which the voltages input to the gate terminals of the transfer transistors 112a and 112b change from High level to Low level. As the amounts of currents that may be output from the buffers 141a and 141b become smaller, a longer time is necessary to accumulate the charges to change the voltage, resulting in longer fall times.

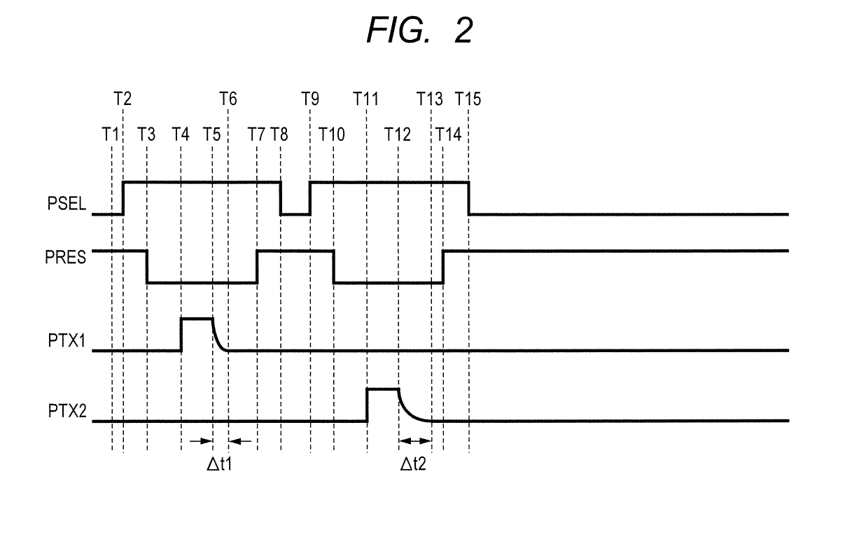

FIG. 2 is a drive timing chart according to the first embodiment of the present invention. In FIG. 2, the control signals PSEL, PRES, PTX1, and PTX2 represent the signals to be input to the select transistor 115, the reset transistor 114, and the transfer transistors 112a and 112b, respectively.

At a time T1, the signal charges corresponding to the amounts of incident light are accumulated in the PDs 111a and 111b. The control signals PSEL, PTX1, and PTX2 are at Low level, and the control signal PRES is at High level. Accordingly, the transfer transistors 112a and 112b are turned off. Because the reset transistor 114 is turned on, the FD 116 is reset to the reset electric potential Vd. Because the select transistor 115 is turned off, no signal is output to the vertical output line 170.

At a time T2, the control signal PSEL becomes High level, and the select transistor 115 is turned on. Then, the pixel 110 and the vertical output line 170 are electrically connected to each other, and the amplifier transistor 113 operates as a source follower. Specifically, a voltage corresponding to the voltage of the FD 116 is output to the readout circuit 130 through the vertical output line 170. At a time T3, the control signal PRES becomes Low level, and the reset transistor 114 is turned off. Then, the FD 116 becomes floated, and the reset state thereof is released.

In the period from a time T4 to a time T5, the control signal PTX1 becomes High level, and the transfer transistor 112a is turned on. Then, the signal charges accumulated in the PD 111a are transferred to the FD 116. Depending on the amount of transferred signal charges, the signal voltage to be output to the readout circuit 130 is changed.

The period from the time T5 to a time T6 is a fall time Δt1 during which the control signal PTX1 falls from High level to Low level. As described above, the fall time Δt1 may be controlled by the current control circuit 121.

At a time T7, the control signal PRES becomes High level, and the reset transistor 114 is turned on so that the FD 116 is reset to the reset electric potential Vd again. At a time T8, the control signal PSEL becomes Low level, and the select transistor 115 is turned off to cancel the select of the row. At a time T9, the control signal PSEL becomes High level again, and the select transistor 115 is turned on to select the row. At a time T10, the control signal PRES becomes Low level, and the reset transistor 114 is turned off. Then, the FD 116 becomes floated.

In the period from a time T11 to a time T12, the control signal PTX2 becomes High level, and the transfer transistor 112b is turned on. Then, the signal charges accumulated in the PD 111b are transferred to the FD 116. Depending on the amount of transferred signal charges, the voltage of the FD 116 is changed and then the signal voltage is output to the readout circuit 130.

The period from the time T12 to a time T13 is a fall time Δt2 during which the control signal PTX2 falls from High level to Low level. The fall time Δt2 may similarly be controlled by the current control circuit 121. The drive timing for the fall time Δt2 is different from that for the fall time Δt1. Accordingly, by changing the control signal from the current control circuit 121, the fall time Δt2 may be adjusted to any value independently from the fall time Δt1. In other words, the length of the period during which the voltage input to the gate terminal of the transfer transistor changes may be adjusted to be different from one transfer transistor to another. FIG. 2 illustrates the case where the fall time Δt1 is set to be shorter than the fall time Δt2, but instead the fall time Δt1 may be shorter than the fall time Δt2.

At a time T14, the control signal PRES becomes High level, and the reset transistor 114 is turned on to reset the FD 116. At a time T15, the control signal PSEL becomes Low level, and the select transistor 115 is turned off to cancel the select of the row. Through the operation described above, the signals from the PDs 111a and 111b are read individually as signals in another row.

Next, the reason why it is advantageous that the fall times Δt1 and Δt2 at the time of transfer of charges of the PDs 111a and 111b are controlled by the current control circuit 121 so as to be different from each other is described. In the following description, it is assumed that the charges to be generated by the PDs 111a and 111b are electrons having negative charges, and the reset electric potential of the FD 116 is positive. It is also assumed that the transfer transistors 112a and 112b are N-channel transistors. In this case, the potential of the FD 116 is lower than the potentials of the PDs 111a and 111b in terms of electrons, and hence when the transfer transistors 112a and 112b are turned on, electrons are transferred from the PDs 111a and 111b to the FD 116. After the electrons are transferred to the FD 116, the electric potential of the FD 116 is decreased.

Parasitic capacitance exists between the transfer signal lines 145a and 145b and the FD 116. When the input levels of the control signals PTX1 and PTX2 are changed from Low level to High level so that the electric potentials of the transfer signal lines 145a and 145b are increased, the electric potential of the FD 116 that is capacitively coupled with the transfer signal lines 145a and 145b is also increased. This increase amount depends on the layout of the entire pixel 110, including the amplifier transistor 113, the reset transistor 114, and the select transistor 115. The layout may not be completely symmetric with respect to the arrangement of the transfer signal lines 145a and 145b. For this reason, the electric potential increase amount of the FD 116 may be different between when the control signal PTX1 becomes High level and when the control signal PTX2 becomes High level.

Now consider the case where the control signals PTX1 and PTX2 abruptly change to Low level after electrons are transferred from the PDs 111a and 111b to the FD 116, that is, the case where the fall time is short. In this case, a phenomenon occurs that a part of electrons remaining below the gates of the transfer transistors 112a and 112b are not transferred to the FD 116 but return to the PDs 111a and 111b. In the following, electrons that return to the PDs due to this phenomenon are referred to as “residual electrons”. When the electric potential increase amount of the FD 116 due to capacitance coupling is small and the electric potential thereof is low, the electric potential difference between the FD 116 and the PDs 111a and 111b is reduced to increase the amount of residual electrons. Accordingly, the amount of electrons to be transferred to the FD 116 is reduced, and the voltage to be output from the pixel 110 becomes higher than the original signal voltage. On the other hand, when the electric potential increase amount of the FD 116 due to capacitance coupling is large and the electric potential thereof is high, the amount of electrons to be transferred to the FD 116 is increased, and the voltage to be output from the pixel 110 becomes lower than the original signal voltage. Thus, even when the same amount of charges is generated from the PDs, the voltage to be output from the pixel 110 may not be the same due to the difference in electric potential increase amount of the FD. As described above, a different error may be generated in the output signal depending on the PD, and hence image quality degradation such as horizontal shading may occur at the time of imaging.

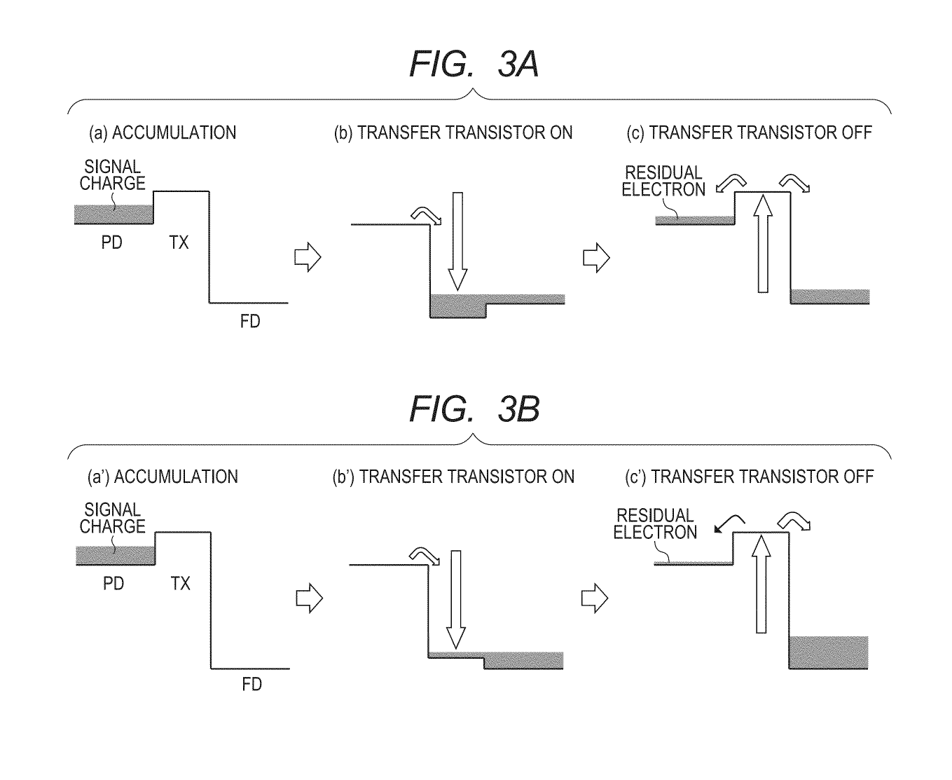

FIGS. 3A and 3B are schematic diagrams illustrating change in potentials of the PD, the FD, and a portion below the gate of the transfer transistor (TX) and the movement of signal charges at the time of transfer of the signal charges. FIG. 3A illustrates the movement of charges when the electric potential increase amount of the FD 116 due to capacitance coupling is large, and FIG. 3B illustrates the movement of charges when the electric potential increase amount of the FD 116 due to capacitance coupling is small. In the following, the former is referred to as “the case where the electric potential of the FD is high”, and the latter is referred to as “the case where the electric potential of the FD is low”. Because electrons have negative charges, the potential becomes lower as the electric potential becomes higher. Parts (a) to (c) of FIG. 3A are schematic diagrams illustrating the case where the electric potential of the FD is low. Parts (a′) to (c′) of FIG. 3B are schematic diagrams illustrating the case where the electric potential of the FD is high.

Part (a) of FIG. 3A illustrates the potentials when the signal charges are accumulated in the PD. Because the transfer transistor is turned off, the signal charges are blocked by the potential of the transfer transistor and do not move to the FD. Part (b) of FIG. 3A illustrates that the potential of the TX decreases because the transfer transistor is turned on. In this case, the signal charges accumulated in the PD are transferred to the FD having low potential. In the case where the electric potential of the FD is low, that is, the potential of the FD is high, a part of the charges are apt to remain in the TX. Part (c) of FIG. 3A illustrates that the gate voltage of the TX is set to Low level after the state of part (b) of FIG. 3A. In this case, a part of the signal charges remaining in the TX return to the PD as residual electrons.

On the other hand, in parts (a′) to (c′) of FIG. 3B illustrating the case where the electric potential of the FD is high, a smaller amount of signal charges than that in the above-mentioned case remains in the TX because the electric potential of the FD is high, that is, because the potential of the FD is low. Accordingly, as illustrated in part (c′) of FIG. 3B, the amount of residual electrons is smaller than that in the case of part (c) of FIG. 3A. For the reason described above, the amount of residual electrons becomes smaller as the electric potential increase amount of the FD becomes larger when the gate voltage of the transfer transistor is set to High level.

Further, the amount of residual electrons is reduced when the fall time of the control signal of the transfer transistor is lengthened. The reason is that a longer fall time facilitates the movement of signal charges remaining in the TX to the FD having a lower potential than the PD in the course of fall. Consequently, when the fall time is lengthened, the amount of residual electrons in the PD may be reduced.

Meanwhile, as the length of interconnect from the vertical scanning circuit 120 to the transfer transistor 112a or 112b becomes larger, larger resistance and capacitance are generated in the interconnect. Because a delay period becomes longer as the resistance and the capacitance become larger, the gate input voltage of the transfer transistor 112a or 112b has the waveform in which the pulse is rounded at rise and fall. Accordingly, the fall time is lengthened to reduce the amount of residual electrons. In other words, as the distance between the vertical scanning circuit 120 and the pixel 110 becomes larger with longer interconnect, the amount of residual electrons is reduced to increase the output voltage, and hence the image quality may degrade due to horizontal shading.

As described above, the increase amount of the electric potential of the FD 116 varies between the transfer of charges for the row of the PD 111a and the transfer of charges for the row of the PD 111b. This difference in electric potential increase amount causes a difference in how much the image quality degrades due to horizontal shading among rows. In order to reduce the image quality degradation caused by this factor, the fall time needs to be lengthened to reduce the amount of residual electrons. However, if the fall times are to be uniformly lengthened for the PDs 111a and 111b, the fall times need to be set so as to be suitable for one of the PDs that more affects the amount of residual electrons. In this case, an unnecessarily long fall time is set for the other PD that less affects the amount of residual electrons.

In this embodiment, the fall time may be controlled depending on the amount of residual electrons through independent control of currents flowing through the constant current sources 142a and 142b. In other words, the fall times Δt1 and Δt2 may be differently set depending on the amount of residual electrons. Then, by shortening the fall time for one of the PDs that less affects the amount of residual electrons, the image quality degradation due to horizontal shading may be reduced.

In the timing chart according to this embodiment illustrated in FIG. 2, the case where the fall time Δt1 is set to be shorter than the fall time Δt2 because the PD 111b has a larger amount of residual electrons than the PD 111a is exemplified. In this example, the fall time Δt1 may be shortened.

On the other hand, in the case where the PD 111a has a larger amount of residual electrons than the PD 111b in contrast to the timing chart of FIG. 2, the fall time Δt2 is set to be shorter than the fall time Δt1. In this case, the fall time Δt2 may be shortened.

As described above, this embodiment may provide a solid-state imaging apparatus in which the signal read period is shortened while the image quality is maintained. Note that, the method of controlling the fall time according to the present invention is not limited to a method involving controlling the output currents of the buffers 141a and 141b by the constant current sources 142a and 142b. The same effects may be obtained as long as the fall times of the respective control signals may be adjusted independently from each other, for example by adjusting the capacitance and resistance generated in the transfer signal lines 145a and 145b so as to change the delay period of the transfer signal.

### Second Embodiment

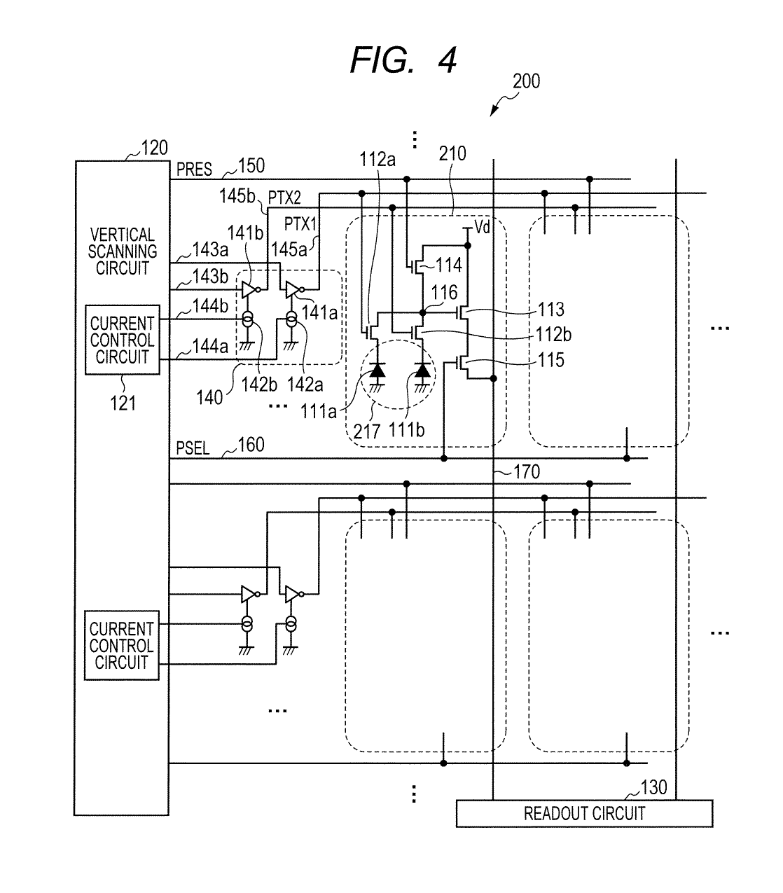

FIG. 4 illustrates a circuit configuration of a solid-state imaging apparatus according to a second embodiment of the present invention. A solid-state imaging apparatus 200 according to this embodiment is configured to obtain a focus detection signal to be used for pupil-divided focus detection. Accordingly, the PDs 111a and 111b share a single microlens 217. The other components are the same as those in FIG. 1, and hence a description thereof is omitted.

Signals output from the PDs 111a and 111b are referred to as “signal A” and “signal B”, respectively. The signal A and the signal B are used to detect a distance between the solid-state imaging apparatus 200 and a subject based on a phase difference of the two signals. After the signal A is read, the signal A is added to the signal B in the FD 116, to thereby read a signal A+B as an image signal. In this case, a difference acquisition unit (not shown) obtains a difference between the signal A+B and the signal A to obtain a signal corresponding to the signal B. The difference acquisition unit may be an analog circuit such as a comparator, or may be a logic circuit, a program, or the like for subtracting digital data. In this manner, the circuit of FIG. 4 reads the signal A and the signal B used for focus detection, and also reads the signal A+B as an image signal in parallel. The signal A and the signal B may be read from a pixel 210 independently from each other.

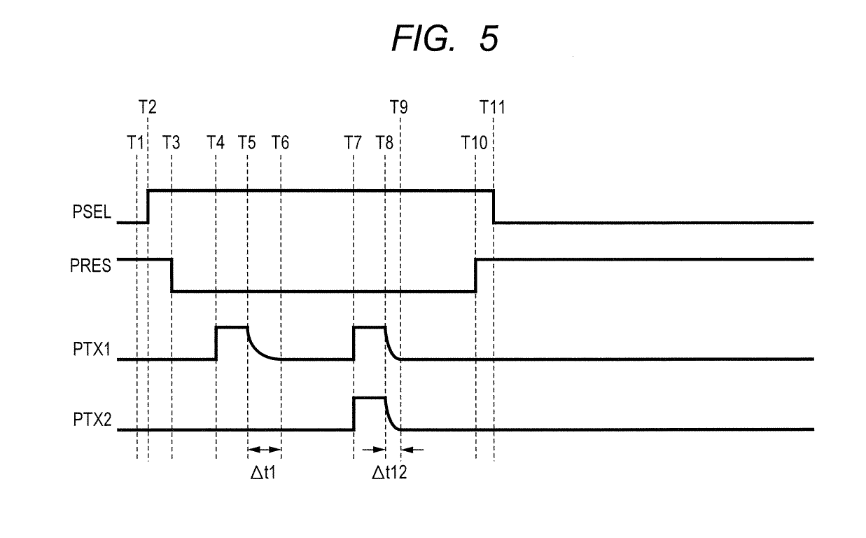

FIG. 5 is a drive timing chart of the solid-state imaging apparatus according to the second embodiment. Referring to this drive timing chart, a driving method in which the signal A is read and then the signal A+B obtained by adding the signal A and the signal B together is read is described. A description of the same operation as that in the first embodiment is omitted.

In the period from a time T4 to a time T5, the first control signal PTX1 becomes High level, and the transfer transistor 112a is turned on. Then, signal charges (signal A) accumulated in the PD 111a are transferred to the FD 116. Depending on the amount of transferred signal charges, the signal voltage to be output to the readout circuit 130 is changed. The signal A output from the readout circuit 130 is used as a signal for focus detection.

The period from the time T5 to a time T6 is a fall time Δt1 during which the first control signal PTX1 falls from High level to Low level. As described above, the fall time Δt1 may be controlled by the current control circuit 121.

In the period from a time T7 to a time T8, the first control signal PTX1 and the second control signal PTX2 become High level simultaneously, and the transfer transistors 112a and 112b are turned on. The charges corresponding to the signal A, which are transferred from the PD 111a, and the charges corresponding to the signal B, which are transferred from the PD 111b, are added together in the FD 116. Then, the added signal is output to the readout circuit 130 as an image signal (signal A+B).

The period from the time T8 to a time T9 is a fall time Δt12 during which the first and second control signals PTX1 and PTX2 fall from High level to Low level. The fall time Δt12 is controlled by the current control circuit 121. The drive timing for the fall time Δt12 is different from that for the fall time Δt1. Accordingly, by changing the control signal from the current control circuit 121, the fall time Δt12 may be adjusted to any value independently from the fall time Δt1. In this embodiment, the fall time Δt12 is controlled to be shorter than the fall time Δt1.

Now, the reason why it is advantageous to shorten the fall time Δt12 than the fall time Δt1 is described. At the time T4 at which the signal A is read, the electric potential of the FD increases due to capacitance coupling only with the transfer signal line 145a. On the other hand, at the time T7 at which the signal A+B is read, the electric potential of the FD increases more greatly than the above due to capacitance coupling with the two transfer signal lines 145a and 145b. In other words, the electric potential of the FD at the time of transfer becomes higher to reduce the influence of residual electrons when the signal A+B is read than when the signal A is read. Accordingly, even when the fall time Δt12 for the signal A+B is shorter than the fall time Δt1 for the signal A, the residual electrons are sufficiently reduced. Consequently, by setting the relationship of the fall times to Δt1>Δt12, the transfer period is shortened.

### Third Embodiment

A third embodiment of the present invention is a modification of the drive method of the second embodiment. The circuit configuration is the same as that in the second embodiment, and hence a description thereof is omitted.

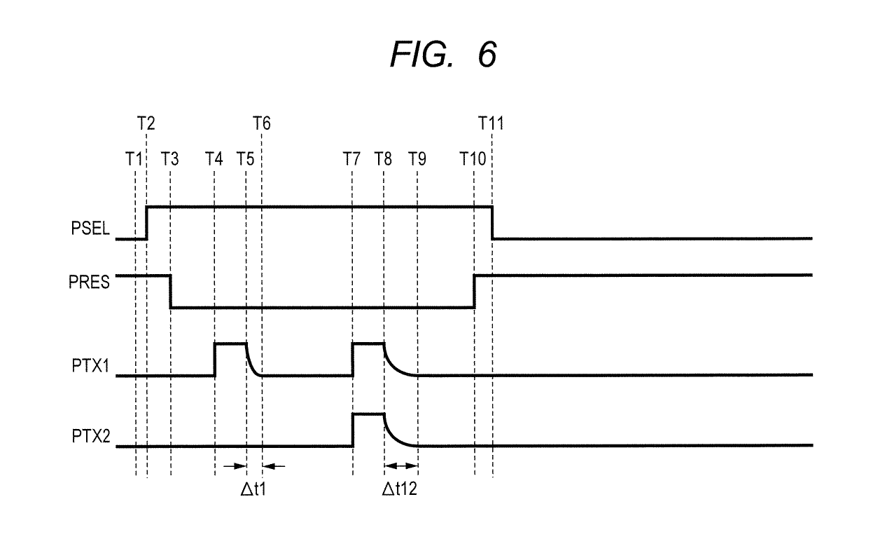

FIG. 6 is a drive timing chart of a solid-state imaging apparatus according to the third embodiment of the present invention. The difference of the third embodiment from the second embodiment resides in the relationship of the lengths of the fall times Δt1 and Δt12. Specifically, the difference resides in that the fall times in the second embodiment have the relationship of Δt1>Δt12 but the fall times in the third embodiment have the relationship of Δt12>Δt1. In this manner, residual electrons may be reduced more at the time of reading the signal A+B than at the time of reading the signal A.

In a case where the difference between the electric potential of the FD at the time of reading the signal A and the electric potential of the FD at the time of reading the signal A+B is negligibly small, the signal A and the signal A+B have substantially the same error even when the respective control signals are set to have the same fall time. In this case, the signal A+B serving as an image signal, which affects image quality, needs to have a smaller error than the signal A used for focus detection. On the other hand, the signal A needs to be read at high speed. Accordingly, by shortening the fall time Δt1 for reading the signal A than the fall time Δt12, the transfer period may be shortened and the image quality may be improved.

In the first to third embodiments, the voltages of the control signals PTX1 and PTX2 at the fall may change continuously, like a straight line or a curved line, or may change discontinuously at least in part, like a step.

### Fourth Embodiment

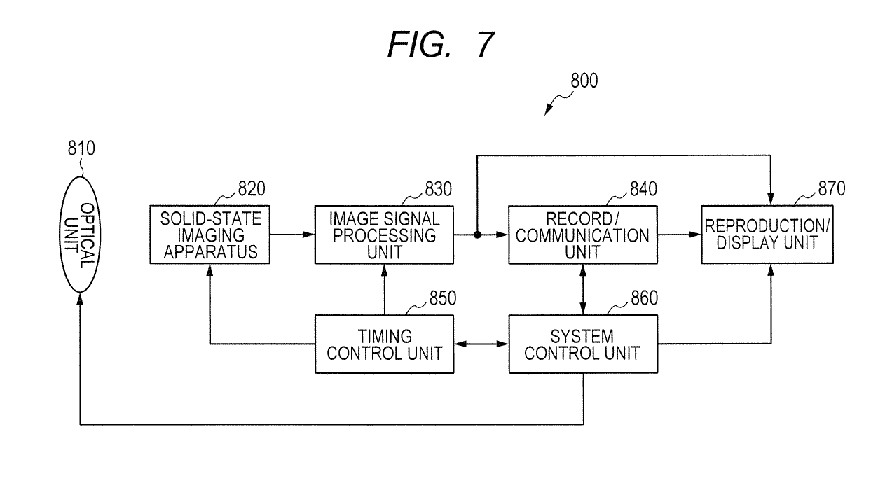

FIG. 7 is a diagram illustrating a configuration of an imaging system according to a fourth embodiment of the present invention. An imaging system 800 includes an optical unit 810, a solid-state imaging apparatus 820, an image signal processing unit 830, a record/communication unit 840, a timing control unit 850, a system control unit 860, and a reproduction/display unit 870. As the solid-state imaging apparatus 820, the solid-state imaging apparatus including the configuration described in any one of the first to third embodiments may be used. The optical unit 810, which is an optical system such as a lens, forms an image of light from a subject on a pixel array of the solid-state imaging apparatus 820 in which the plurality of pixels 110 are two-dimensionally arranged, to thereby form an image of the subject.

The solid-state imaging apparatus 820 outputs a signal corresponding to the light whose image is formed on the pixel array at the timing based on a signal transmitted from the timing control unit 850. The signal output from the solid-state imaging apparatus 820 is input to the image signal processing unit 830 after being subjected to processing such as AD conversion. The image signal processing unit 830 performs signal processing, such as conversion of the input signal into image data, in accordance with a method determined by a program or the like. The signal obtained through the processing in the image signal processing unit 830 is transmitted to the record/communication unit 840 as image data. The record/communication unit 840 transmits a signal for forming an image to the reproduction/display unit 870, to thereby cause the reproduction/display unit 870 to reproduce or display a moving image or a still image. Further, in response to the signal from the image signal processing unit 830, the record/communication unit 840 communicates to/from the system control unit 860 and records the signal for forming an image in a recording medium (not shown).

The system control unit 860 controls the operation of the imaging system 800 in a comprehensive manner, and controls the drive of the optical unit 810, the timing control unit 850, the record/communication unit 840, and the reproduction/display unit 870. Further, the system control unit 860 includes a memory device (not shown), such as a recording medium. A program and the like necessary for controlling the operation of the imaging system 800 are recorded in the memory device. Further, the system control unit 860 supplies the imaging system with a signal for switching a drive mode in accordance with a user's operation, for example. Specifically, the system control unit 860 supplies the imaging system with a signal for performing switching, such as the change of a row to be read or a row to be reset, the change of the angle of view accompanying electronic zooming, and the shift of the angle of view accompanying electronic image stabilization. The timing control unit 850 controls drive timings of the solid-state imaging apparatus 820 and the image signal processing unit 830 based on the control by the system control unit 860.

The solid-state imaging apparatus 820 used in this embodiment shortens the readout period. Consequently, according to this embodiment, by mounting the solid-state imaging apparatus 820, the imaging system 800 capable of photographing at high speed with a large number of images to be taken per unit time may be implemented.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2014-075060, filed Apr. 1, 2014 which is hereby incorporated by reference herein in its entirety.

What is claimed is:

1. A solid-state imaging apparatus, comprising:
a plurality of photoelectric conversion elements each configured to generate charges by photoelectric conversion; and
a plurality of transfer transistors, which are connected to the plurality of photoelectric conversion elements, respectively, each configured to transfer the generated charges to the same floating diffusion,
wherein the plurality of transfer transistors are configured to be on/off controlled based on a voltage input to a gate terminal thereof, and
wherein a length of a period during which the voltage input to the gate terminal changes when a corresponding one of the plurality of transfer transistors is switched from on to off varies from one transfer transistor to another.

2. A solid-state imaging apparatus according to claim 1, further comprising:
a vertical scanning circuit configured to output a control signal for on/off controlling the plurality of transfer transistors;
a buffer unit, which is connected between the vertical scanning circuit and the gate terminals of the plurality of transfer transistors, configured to buffer the control signal to output the buffered control signal to the gate terminals of the plurality of transfer transistors; and
a current control circuit configured to control, for each of the plurality of transfer transistors, a length of a period during which the voltage input to the gate terminal of the transfer transistor changes from a voltage for turning on the transfer transistor to a voltage for turning off the transfer transistor, by controlling a current to be supplied from the buffer unit.

3. A solid-state imaging apparatus according to claim 1,
wherein the plurality of transfer transistors comprise a first transfer transistor and a second transfer transistor,
wherein an electric potential of the floating diffusion becomes higher at a time when the first transfer transistor is turned on than at a time when the second transfer transistor is turned on, and
wherein a length of a period during which a voltage input to a gate terminal of the first transfer transistor changes when the first transfer transistor is switched from on to off is shorter than a length of a period during which a voltage input to a gate terminal of the second transfer transistor changes when the second transfer transistor is switched from on to off.

4. A solid-state imaging apparatus according to claim 2,
wherein the plurality of photoelectric conversion elements are arranged in matrix, and
wherein the current control circuit controls the control signal for each of the rows of the photoelectric conversion elements.

5. A solid-state imaging apparatus according to claim 2,
wherein the vertical scanning circuit is configured to transmit:
a first control signal for on/off controlling one of the plurality of transfer transistors; and
a second control signal for on/off controlling another one of the plurality of transfer transistors,
wherein transfer of charges based on the second control signal is performed after transfer of charges based on the first control signal, and
wherein a length of a period during which a voltage input to a gate terminal of the one of the plurality of transfer transistors controlled based on the first control signal changes when the one of the plurality of transfer transistors is switched from on to off is different from a length of a period during which a voltage input to a gate terminal of the another one of the plurality of transfer transistors controlled based on the second control signal changes when the another one of the plurality of transfer transistors is switched from on to off.

6. A solid-state imaging apparatus according to claim 5, wherein the charges transferred based on the first control signal and the charges transferred based on the second control signal are added in the same floating diffusion.

7. A solid-state imaging apparatus according to claim 5, wherein, when the second control signal is transmitted, the first control signal is also transmitted in parallel.

8. A solid-state imaging apparatus according to claim 1, further comprising a microlens shared by the plurality of photoelectric conversion elements which transfer the charges to the same floating diffusion.

9. A solid-state imaging apparatus according to claim 1, wherein the voltage input to the gate terminal changes continuously.

10. A solid-state imaging apparatus according to claim 1, wherein the voltage input to the gate terminal changes discontinuously at least in part.

11. An imaging system, comprising the solid-state imaging apparatus of claim 1.
